(19) United States
(12) Patent Application Publication
(10) Pub. No.: US 2007/0146103 A1
(43) Pub. Date: Jun. 28, 2007

(54) Resistor board and attenuator having the same

(75) Inventor: Hiroaki Nishimura, Tokyo (JP)

Correspondence Address: TAKEUCHI & KUBOTERA, LLP, SUITE 202, 200 DAINGERFIELD ROAD, ALEXANDRIA, VA, 22314, US

(73) Assignee: Hirose Electric Co., Ltd.

(21) Appl. No.: 11/638,552

(22) Filed: Dec. 14, 2006

(30) Foreign Application Priority Data
Dec. 28, 2005 (JP) 2005-379105

(51) Int. Cl. H01P 1/22; H03H 7/24

(52) U.S. Cl. 333/81 A

(57) ABSTRACT

A resistor board for attenuating a signal, includes: a first signal section for receiving the signal; a second signal section for outputting the signal; and at least two signal lines disposed between the first signal section and the second signal section. Each of the signal lines includes a first resistor section, a first signal transmission section, and a second resistor section respectively arranged in series. The first resistor section and the second resistor section are formed of a first resistor layer. The first signal transmission section is formed of the first resistor layer and a first metal layer. The resistor board further includes a ground section for attenuating the signal, and a first ground line disposed between the ground section and at least one of the signal lines. The first ground line includes a third resistor section formed of the first resistor layer.

### BACKGROUND OF THE INVENTION AND RELATED ART STATEMENT

The present invention relates to a resistor board and an attenuator having the resistor board.

An attenuator with a resistor board disposed therein for attenuating a signal has been developed. Examples of resistor boards 120A to 120D used in this type of attenuators are shown in FIGS. 9(a) to 9(d).

Each of the resistor boards 120A to 120D is provided with signal sections 128A and 128B arranged oppositely; ground sections 129A and 129B arranged oppositely in a direction perpendicular to the signal sections; and resistor sections 121A to 121D having a single shape without a center and a ground.

A signal flows between the signal section 128A and the signal section 128B. The signal is connected to the ground sections 129A and 129B through the resistor sections 121A to 121D, thereby attenuating the signal. In particular, in the resistor patterns of the resistor sections 121A to 121D, for example, an area and a shape are different according to a desired attenuation level. For example, the resistor sections 121A to 121D shown in FIGS. 9(a) to 9(d) achieve the attenuation level of 3 dB, 6 dB, 10 dB, and 20 dB, respectively. The attenuation level of the resistor pattern is controlled by an oxidation time of the resistor board and a degree of oxidation.

In the conventional resistor boards described above, the attenuation level of the resistor pattern is controlled by an oxidation time and intensity. In general, it is difficult to adjust these conditions. Accordingly, it is difficult to form a resistor pattern having a desired attenuation level. Further, when the resistor board is produced with such an oxidation method, the resistor board tends not to properly withstand high frequency wave. Further, it is necessary to trim the resistor shape to adjust a resistor value, thereby taking long time to process and making it difficult to improve accuracy.

In view of the problems described above, an object of the present invention is to provide a resistor board in which it is easy to produce a resistor shape having a desired pattern. A further object is to provide an attenuator with such a resistor board disposed therein.

Further objects will be apparent from the following description of the invention.

### SUMMARY OF THE INVENTION

According to the present invention, a resistor board for attenuating a signal includes: a first signal section for receiving the signal; a second signal section for outputting the signal; and at least two signal lines disposed between the first signal section and the second signal section for electrically connecting the first signal section and the second signal section. Each of the signal lines includes a first resistor section, a first signal transmission section, and a second resistor section respectively arranged in series. The first resistor section and the second resistor section are formed of a first resistor layer. The first signal transmission section is formed of the first resistor layer and a first metal layer. The resistor board further includes a ground section for attenuating the signal, and a first ground line disposed between the ground section and at least one of the signal lines for electrically connecting the ground section and the at least one of the signal lines. The first ground line includes a third resistor section formed of the first resistor layer.

In the resistor board, a hollow portion where the resistor layer or the metal layer does not exist may be formed in an area surrounded by the two signal sections and the two signal lines.

In the resistor board, the resistor block pattern having the T character shape may be connected in parallel. Alternatively, the resistor block pattern may have the π character shape, and the resistor block pattern having the π character shape may be connected in parallel. Further, it is possible to provide an attenuator disposing the resistor board according therein.

According to the present invention, it is possible to easily form a desirable pattern on the resistor board. Further, it is possible to provide the attenuator disposing the resistor board therein.

### BRIEF DESCRIPTION OF THE DRAWINGS

FIG. 1 is sectional view of an attenuator partially broken along a centerline thereof according to an embodiment the present invention;

FIG. 2 is a sectional perspective view of a second part;

FIG. 3 is a view showing an assembly process of the second part at an intermediate stage;

FIG. 4 is view showing the assembly process of the second part at a completed state;

FIG. 5 is a sectional view of the second part shown in FIG. 4;

FIG. 6 is a plan view of a resistor board;

FIG. 7 is a view showing a resistor circuit of the resistor board shown in FIG. 6;

FIGS. 8(a) to 8(c) are views of resistor boards according to other embodiments of the present invention; and

FIGS. 9(a) to 9(d) are views showing conventional resistor boards.

### DETAILED DESCRIPTION OF PREFERRED EMBODIMENTS

Hereunder, a resistor board and an attenuator having the resistor board therein according to an embodiment of the present invention will be explained with reference to the accompanying drawings.

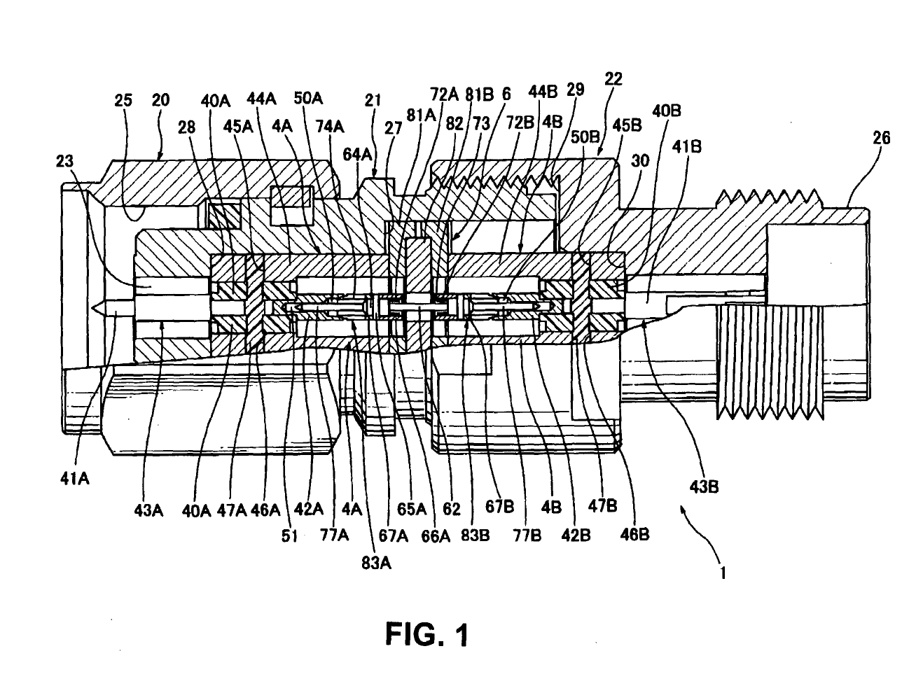

FIG. 1 is sectional view of an attenuator 1 partially broken along a centerline thereof according to an embodiment the present invention. A resistor board can be installed in the attenuator 1. The attenuator 1 is formed of three portions with substantially cylindrical shapes to be mutually fixed coaxially, i.e., a screw portion 20, a first shell 21, and a second shell 22.

The screw portion 20 is provided for connecting the attenuator 1 to a mating coaxial connector (not shown), and is fixed to the first shell 21 such that the screw portion 20 covers a part of a front portion of the first shell 21. The second shell 22 is fixed to the first shell 21 such that the screw portion 20 covers a part of a rear portion of the first shell 21. The first shell 21 can accommodate a first part 4A and a second part 6 therein, while the second shell 22 accommodates a part of a rear end of the first part 4A therein.

The screw portion 20 has a screw portion cut out around a centerline thereof with a specific diameter for retaining one end of the first shell 21. It is possible to attach the screw portion 20 to another mating connector having a connecting part with a shape same as that of a rear end portion 26 of the second shell 22. Accordingly, it is possible to connect two coaxial connectors to the attenuator 1.

The first shell 21 has a step portion cut out around a centerline thereof, and the step portion has a plurality of inner diameters. It is set such that the inner diameter decreases toward a forward direction. A flange 27 is formed between a large diameter portion and a middle diameter portion, and a flange 28 is formed between the middle diameter portion and a small diameter portion, respectively. The flange 27 is disposed at a position facing a front side of the second part 6, and the flange 28 prevents collision with a front side of the first part 4A and coming off from a front side of the first shell 21.

The first shell 22 has a step portion cut out around a centerline thereof, and the step portion has a plurality of inner diameters. It is set such that the inner diameter increases toward the forward direction. A flange 29 is formed between a large diameter portion and a middle diameter portion, and a flange 30 is formed between the middle diameter portion and a small diameter portion, respectively.

The rear end portion 26 with a screw portion has a relatively large inner diameter to be connected to a specific connector part (now shown). The flange 29 is disposed at a position facing a rear side of the first shell 21, and the flange 30 prevents collision with a rear side of the first part 4B and coming off from a rear side of the second shell 22.

A part of an inner surface 25 of the screw portion 20 may be formed in a screw shape close to a side facing the first shell 21. When the screw portion is connected in an axial direction to a specific part (for example, a screw portion formed around a coaxial cable and a circumference thereof), it is possible to connect the attenuator 1 to the mating coaxial connector through the screw portion 20.

The first part 4A, the second part 6, and the first part 4B are inserted into the first shell 21 in this order in a specific direction in a state that the part of the first part 4A abuts against the flange 28 of the first shell 21. Afterward, the second shell 22 is fixed to the rear end of the first shell 21. Accordingly, the first part 4A, the second part 6, and the first part 4B are retained and held completely inside the attenuator 1. At the same time, it is possible to maintain a constant distance between the parts at least in the axial direction. It is possible to provide the attenuator 1 with various functions through changing a function of the second part 6. For example, when the second part 6 is provided with a resistor board 62, the attenuator 1 can function as an attenuator.

In the embodiment described above, the connection to the mating coaxial connector is achieved through the screw portion of the screw portion 20, and may be achieved through push-on-lock (simple lock). The connection to the mating connector is not limited to these methods. Further, the screw portion 20 may be provided in the mating coaxial connector.

Configurations of the first parts 4A and 4B will be explained next in more detail. The attenuator 1 has two first parts 4A and 4B. To distinguish them, each part and components constituting the part are designated with letters A and B as necessary. The first part 4A and the first part 4B can be considered to have an identical shape except that a first male terminal 41A and a first female terminal 41B have slightly different shapes. The first part 4A and the first part 4B are disposed in a left-right symmetry arrangement in a state that the second part 6 is assembled.

The first part 4A is formed of a terminal portion 43A having the first male terminal 41A and a second female terminal 42A arranged at opposite positions through an insulation base 40A, and an outer conductor 44A supported and fixed to the terminal portion 43A and surrounding an outer circumference of the terminal portion 43A.

The first part 4B is formed of a terminal portion 43B having a first female terminal 43B and a second female terminal 42B arranged at opposite positions through an insulation base 40B, and an outer conductor 44B supported and fixed to the terminal portion 43B and surrounding an outer circumference of the terminal portion 43B. While the first female terminal 41A of the first part 4A has a pin shape protruding outward, the first female terminal 43B of the first part 4B has a cylindrical receptacle shape for retaining a first male terminal of the mating coaxial connector. In this aspect, the first part 4A is different from the first part 4B. The difference is attributed to a relationship relative to a shape of the first male terminal of the mating connector, and is not so important here.

In the first parts 4A and 4B, the terminal portions 43A and 43B are fixed to the outer conductors 44A and 44B with a resin. After the terminal portions 43A and 43B are inserted into the outer conductors 44A and 44B, so that alignment holes 45A, 45B, 46A, and 46B passing through centers thereof are aligned, resins 47A and 47B are poured into the alignment holes 45A, 45B, 46A, and 46B, thereby mutually fixing with a desirable orientation.

When the attenuator 1 is used, the outer conductor 44A of the first part 4A is electrically connected to a mating outer conductor (not shown) of the mating connector. The terminal portion 43A of the first part 4A is electrically connected to a center conductor (not shown) of the mating connector at the first male terminal 41A for receiving an electrical signal.

The signal received by the outer conductor 44A then is transmitted to the outer conductor 44B of the first part 4B through first connecting tubes 81A and 81B and a second connecting tube 82 of the second part 6. The signal received by the first male terminal 41A then is transmitted to a relay portion 83A of the second part 6 and the resistor board 62 through the second female terminal 42A, and is transmitted to the first female terminal 41B after being attenuated there.

With the flow of the electrical signal described above, it is possible to connect the mating connector connected to the side of the first shell 21 to the mating connector connected to the side of the second shell 22 using the attenuator 1 in the state that the attenuation function is added.

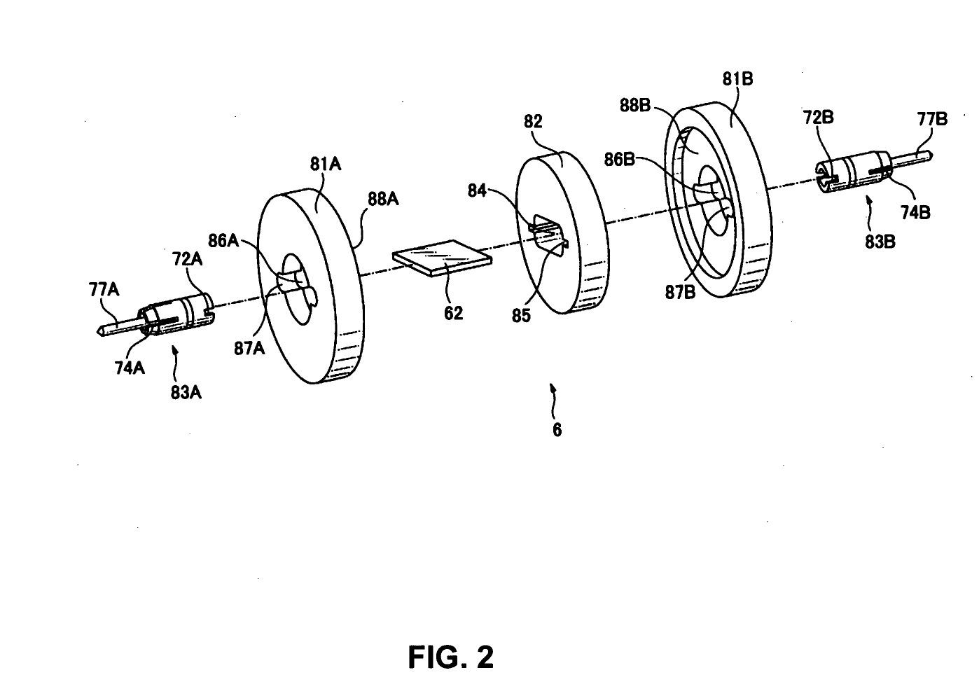

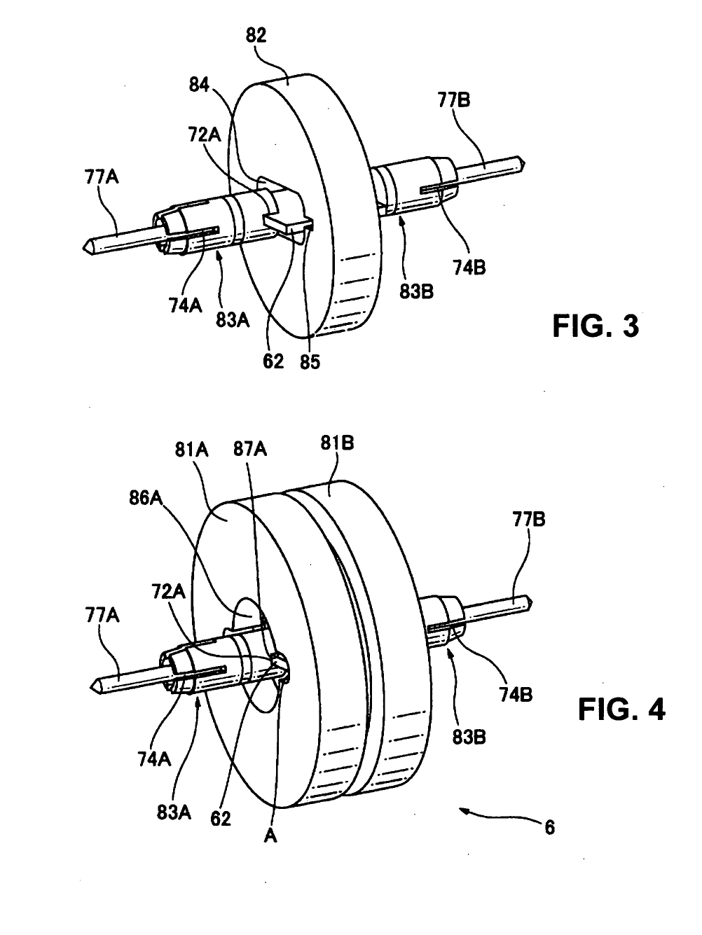

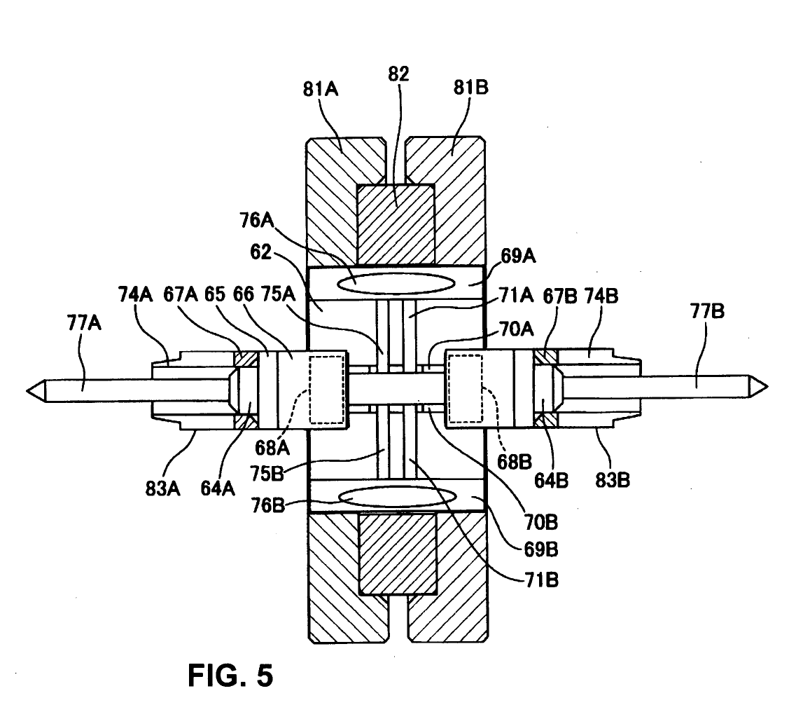

A configuration of the second part 6 will be explained next in more detail with reference to FIGS. 1 to 5. FIG. 2 is a sectional perspective view of the second part 6. FIG. 3 is a view showing an assembly process of the second part 6 at an intermediate stage. FIG. 4 is view showing the assembly process of the second part 6 at a completed state. FIG. 5 is a sectional view of the second part 6 shown in FIG. 4. More specifically, FIG. 5 is a horizontal sectional view taken along an upper surface of the resistor board 62, i.e., one of components of the second part 6.

The second part 6 has a left-right symmetry shape, and includes the second connecting tube 82 disposed at a center thereof; the first connecting tubes 81A and 81B respectively disposed at left and right sides of the second connecting tube 82; the resistor board 62 inserted into the center of the second connecting tube 82 and the first connecting tubes 81A and 81B; and the relay portions 83A and 83B respectively fixed to left and right sides of the resistor board 62.

The second connecting tube 82 is formed of a circular plate member having a specific thickness and good conductivity. A surface of the second connecting tube 82 is formed of a member having compatibility with solder better than that of the first connecting tubes 81A and 81B, that is, suitable for soldering (easy solder sticking), for example, brass with a whole surface plated with gold.

A rectangular hole 84 is formed at the center of the second connecting tube 82. Rectangular paths (grooves) 85 opening at a side of the rectangular hole 84 for receiving the resistor board 62 are formed at left and right positions in a lateral width greater (equal to or lightly greater than a lateral width of the resistor board 62) than a lateral side of the rectangular hole 84.

A vertical width of the rectangular paths 85 is set to be a size substantially equal to or greater than a thickness of the resistor board 62. The resistor board 62 is inserted into the rectangular paths 85 at the left and right sides in a horizontal direction, and is held at opposing sides in the horizontal direction.

Similar to the second connecting tube 82, the first connecting tubes 81A and 81B are formed of a circular plate member having a specific thickness, and have a diameter larger than that of the second connecting tube 82. Different from the second connecting tube 82, although formed of a good conductive member, the first connecting tubes 81A and 81B are formed of a member having poor compatibility with solder (difficult solder sticking) such as aluminum.

Circular holes 86A and 86B having a diameter substantially same as the lateral width of the rectangular hole 84 formed in the second connecting tube 82 are formed at the center of the first connecting tubes 81A and 81B. Further, semi-circular paths (grooves) 87A and 87B opening at sides of the circular holes 86A and 86B for receiving and loosely fitting the resistor board 62 are formed at left and right positions in a lateral width greater (similar to the rectangular paths 85, equal to or lightly greater than the lateral width of the resistor board 62) than a diameter of the circular holes 86A and 86B.

A vertical width of each of the semi-circular paths 87A and 87B is set to be a size greater than the thickness of the resistor board 62, i.e., greater than the vertical width of the rectangular paths 85. Accordingly, the resistor board 62 loosely fits in the semi-circular paths 87A and 87B. Alternatively, a lateral width of each of the semi-circular paths 87A and 87B may be set to be a size greater than the rectangular paths 85, so that the resistor board 62 can loosely fit in the semi-circular paths 87A and 87B in the lateral direction.

Circular recess portions 88A and 88B having a size corresponding to that of the second connecting tube 82 for receiving the second connecting tube 82 are formed in side surfaces of the first connecting tube 81A and 81B. A portion of the second connecting tube 82 having a thickness smaller than a half of the thickness of the second connecting tube 82 is retained in the circular recess portions 88A and 88B formed in the one side surfaces of the first connecting tubes 81A and 81B. Accordingly, it is possible to oppositely arrange the first connecting tubes 81A and 81B with a distance in between.

The first connecting tubes 81A and 81B contact with the second connecting tube 82 using the circular recess portions 88A and 88B of the first connecting tubes 81A and 81B. Through the contact, different metals, i.e., brass plated with gold and aluminum, are combined. Further, the rectangular paths 85 formed in the second connecting tube 82 are aligned on a substantially straight line with the semi-circular paths 87A and 87B formed in the first connecting tubes 81A and 81B. In a state that the resistor board 62 is connected with solder (76A and 76B in FIG. 5) through a capillary tube, the resistor board 62 is installed in the rectangular paths 85 of the second connecting tube 82 and the semi-circular paths 87A and 87B of the first connecting tubes 81A and 81B.

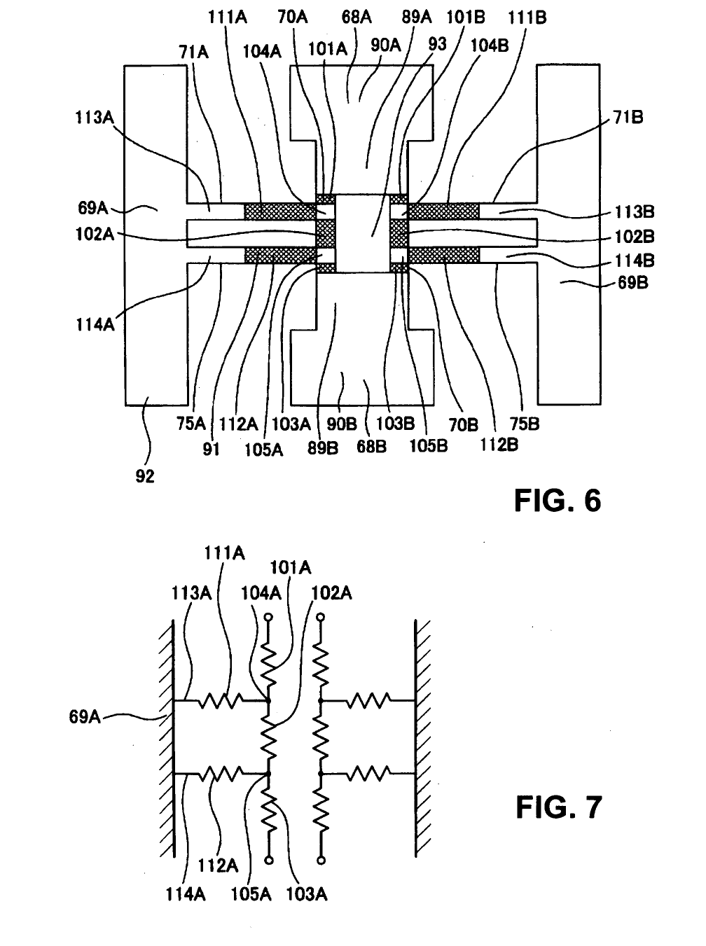

FIG. 6 shows a plan view of the resistor board 62. The resistor board 62 is a chip resistor having a left-right symmetry plate shape. Although not apparent from the drawings, the resistor board 62 has resistor patterns having a same shape on a front side and a backside thereof. The resistor pattern is formed of resistor layers 91 (indicated by hatched lines) and metal layers 92 covering at least parts of the resistor layers 91. A portion having only the resistor layer 91 is formed of one layer, and a portion covered with the metal layer 92 is formed of two layers.

The metal layers 92 have a function of electrically connecting the resistor layers 91 not covered with the metal layers 92, i.e., a portion used as a resistor portion. The resistor portion is connected with a metal electrode. Accordingly, it is possible to shorten a transmission path necessary for signal connection, thereby improving reflection characteristic and decreasing a size. Further, it is possible to obtain a resistor value with high accuracy and a small manufacturing variance.

It is possible to form a desirable pattern on the resistor board 62 using the resistor layers 91 and the metal layers 92. The pattern includes at least signal sections 68A and 68B; ground sections 69A and 69B; signal lines 70A and 70B; and ground lines 71A, 71B, 75A, and 75B. For example, the signal portions 68A and 68B are formed on one pair of opposing sides of the resistor board 62 over a partial length thereof, and the ground sections 69A and 69B are formed on another pair of opposing sides of the resistor board 62 over a whole length thereof.

When the attenuator 1 is assembled, the signal sections 68A and 68B are soldered to the relay portions 83A and 83B, respectively. Through the connection, the mating center conductor of the mating coaxial connector is electrically connected. In order to easily connect the signal sections 68A and 68B to the relay portions 83A and 83B, the signal sections 68A and 68B may have portions having an area relatively larger than center portions 89A and 89B at the connection sides in the drawing, i.e., opposing sides 90A and 90B.

The ground sections 69A and 69B are soldered to the ground sections 69A and 69B of the resistor board 62 at positions near the second connecting tube 82, for example, inside of the rectangular paths 85 passing therethrough and surrounding areas thereof. Through the connection described above and the connection of the second connecting tube 82 and the first connecting tubes 81A and 81B, it is possible to electrically connect to the outer conductors 44A and 44B (refer to FIG. 1) and the mating outer conductor of the mating connector.

Two signal lines 70A and 70B arranged in parallel connect between the signal sections 68A and 68B. The signal lines 70A and 70B are connected to the ground sections 69A and 69B through two ground lines 71A, 71B, 75A, and 75B, respectively. Accordingly, it is possible to flow a signal flowing between the signal sections 68A and 68B down to ground to attenuate.

The metal layers 92 are disposed on the resistor layers 91 to cover whole portions of the signal sections 68A and 68B and the ground sections 69A and 69B, and parts of the signal lines 70A and 70B and the ground lines 71A and 71B. With this method, it is possible to easily design a desirable resistor shape by arranging the resistor layers 91 at proper positions of the resistor board 62.

Further, similar to the resistor layers 91, it is possible to easily design a desirable resistor shape by arranging the metal layers 92 with proper areas at proper positions of the resistor shape designed in advance with the resistor layers 92. As a result, according to the present invention, it is possible to easily obtain a desirable resistor value. Especially when the resistor layers 91 are designed in a combination of rectangular shapes as shown in the figure, it is easy to calculate a resistor value.

A hollow portion 93 where the resistor layer 91 or the metal layer 92 does not exist may be formed in an area surrounded by the signal sections 68A and 68B and the signal lines 70A and 70B. Accordingly, it is possible to reduce a resistor width in a signal direction, i.e., a direction connecting the signal sections 68A and 68B. A signal flowing in the signal direction tends to flow through an edge of a signal transmission path as a frequency of the signal increases.

In the embodiment, the resistors are disposed only at end portions of the signal transmission path, and a width of the resistor is designed to be narrow. Accordingly, it is possible to reduce influence of a signal flowing a portion other than an edge, thereby reducing influence of high frequency waves. Note that even when a low frequency signal flows, the signal does not flow near the hollow portion 93 in the signal direction. Accordingly, the hollow portion 93 can contribute to reduction in noise in the low frequency signal as well.

By providing the metal layers 92 at proper positions of the signal lines 70A and 70B, it is possible to provide, for example, first signal transmission sections 104A and 104B and second signal transmission sections 105A and 105B covered with the metal layers 92; and first signal resistor sections 101A and 101B, second signal resistor sections 102A and 102B, and third signal resistor sections 103A and 103B not covered with the metal layers 92.

In particular, the first signal resistor section 101A(B) is disposed between the signal section 68A and the first signal transmission section 104A(B); the second signal resistor section 102A(B) is disposed between the first signal transmission section 104A(B) and the second signal transmission section 105A(B); and the third signal resistor section 103A(B) is disposed between the second signal transmission section 105A(B) and the signal section 68B. The first signal resistor sections 101A and 101B, the second signal resistor sections 102A and 102B, and the third signal resistor sections 103A and 103B function as a resistor having a resistor value, respectively.

Similarly, by providing the metal layers 92 at proper positions of the ground lines 71A, 71B, 75A, and 75B, it is possible to provide, for example, first ground transmission sections 113A and 113B and second ground transmission sections 114A and 114B covered with the metal layers 92; and first ground resistor sections 111A and 111B, and second ground resistor sections 112A and 112B not covered with the metal layers 92.

In particular, the first ground resistor section 111A(B) is disposed between the first ground transmission section 113A(B) and the first signal transmission section 104A(B) extending from the ground section 69A; and the second ground resistor section 112A(B) is disposed between the second ground transmission section 114A(B) and the second signal transmission section 105A(B) extending from the ground section 69B. The first ground resistor sections 111A and 111B and the second ground resistor sections 112A and 112B function as a resistor having a resistor value, respectively.

The resistor described above corresponds to four resistors connected in parallel as shown in FIG. 7. More specifically, four resistor block patterns connected in parallel are formed of a combination of the first signal resistor section 101A(B), the first signal transmission section 104A(B), the second signal resistor section 102A(B), the first ground resistor section 111A(B), and the first ground transmission section 113A(B); and a combination of the second signal resistor section 102A(B), the second signal transmission section 105A(B), the third signal resistor section 103A(B), the second ground resistor section 112A(B), and the second ground transmission section 114A(B).

In this case, for example, when impedance matching to each resistor block is 200 Ω, the whole circuit of the resistor board 62 matches to impedance of 50 Ω (in the embodiment, impedance is matched at 50 Ω). Considering that the resistor board 62 has the resistor circuits on the front side and the backside thereof, the resistor board 62 has the four resistor block patterns with a T character shape connected in a parallel circuit as a whole.

With the configuration described above, it is possible to connect a plurality of resistor sections, for example, the first signal resistor section 101A(B), the second signal resistor section 102A(B), and the third signal resistor section 103A(B), in series at multiple stages (two stages in the embodiment). In other words, it is possible to connect resistor block patterns having a T character shape in multiple stages (two stages in the embodiment).

Accordingly, it is possible to improve reflection characteristic through the combination of the short transmission paths, and improve transmission characteristic and reflection characteristic at a high attenuation level. Especially in the ground lines 71A, 71B, 75A, and 75B, the resistor layers are formed in a thin band shape to be a resistor having a small resistance width, so that flowing into ground is stabilized. Accordingly, it is possible to obtain stable transmission characteristic over a wide range up to a high frequency.

In the embodiment described above, the resistor patterns having the T character shape are used. Instead of the T character shape, a so-called n character shape may be used. Further, in the embodiment described above, the resistor portions are arranged in the two stages, or the T character patterns are connected in double, and the number of stages or connections can be changed if necessary.

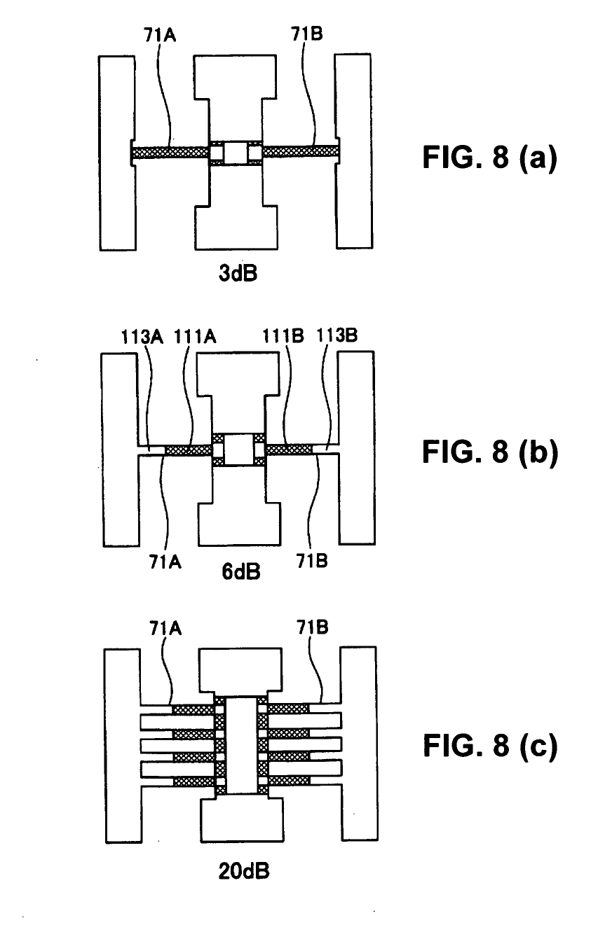

For example, as shown in FIGS. 8(a) and 8(b), one stage or one connection can be applied, or as shown in FIG. 8(c), four stages or four connections can be applied. FIGS. 8(a) and 8(b) show examples having one stage or one connection. In FIG. 8(a), the ground lines 71A and 71B are not covered with the metal layer to achieve 3 dB. In FIG. 8(b), the ground lines 71A and 71B have the ground resistor sections 111A and 111B having a decreased ratio and the ground transmission sections 113A and 113B having an increased ratio to achieve 6 dB.

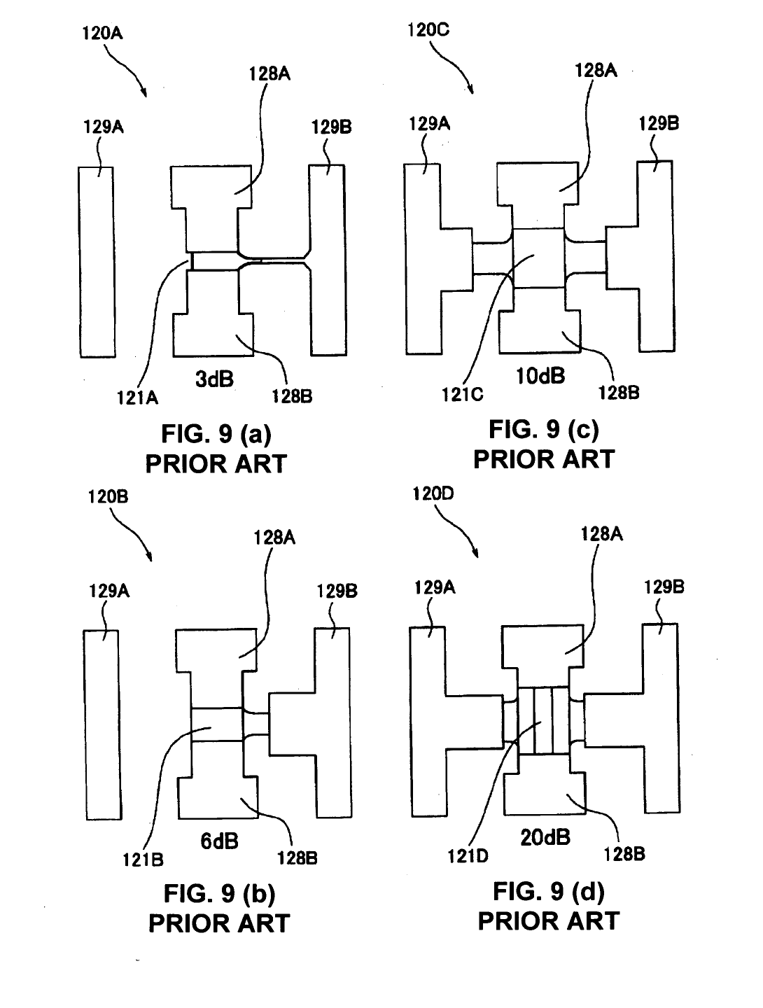

In the example shown in FIG. 8(c), the four stages or four connections are applied to achieve 20 dB, which is double of the two stages or two connections shown in FIG. 6 for achieving 10 dB. FIGS. 8(a), 8(b) and 8(c) correspond to conventional examples shown in FIGS. 9(a), 9(b), and 9(c). The example shown in FIG. 6 corresponds to FIG. 9(c).

A configuration of the relay portions 83A and 83B will be explained next with reference to FIG. 1. The relay portions 83A and 83B include connecting terminals 64A and 64B to be connected to the resistor board 62; connecting tubes 66A and 66B having a cylindrical shape on a side of the second connecting tube 82 and the first connecting tubes 81A and 81B; and relay tubes 67A and 67B having a cylindrical shape on the other side, i.e., a side of the first parts 4A and 4B, with flanges 65A and 65B of the connecting tubes 64A and 64B as boundaries.

Slit members 71A and 71B having a crescent shape section are disposed at end portions of the relay portions 83A and 83B to form slits therebetween. The signal sections 68A and 68B of the resistor board 62 are inserted into cylinders of the slit members 72A and 72B. Afterward, solders 73A and 73B are applied to circumferences of the slit members 72A and 72B, so that the relay portions 83A and 83B are fixed to the resistor board 62. The relay portions 83A and 83B fixed to the resistor board 62 extend outside the first connecting tubes 81A and 81B in a direction from the second connecting tube 82 toward the first connecting tubes 81A and 81B at positions passing through the center of the second connecting tube 82 and the first connecting tubes 81A and 81B.

Although not apparent from the drawings, the solders are applied to whole circumferences of the slit members 72A and 72B (since the drawing is a sectional view with a centerline, this feature is not shown clearly).

When the first parts 4A and 4B are connected to the second part 6, they are elastically connected at least in an axial direction with a spring structure using the relay tubes 67A and 67B of the second part 6 and the second female terminals 42A and 42B of the first parts 4A and 4B.

In order to utilize the spring structure, split portions 74A and 74B are formed in the relay tubes 67A and 67B on a connection side relative to the first parts 4A and 4B in a lateral direction passing through the center. In the configuration, when the first parts 4A and 4B approach the second part 6 in the axial direction, guide pins 77A and 77B are guided into entrance holes 50A and 50B of the second female terminals 42A and 42B of the first parts 4A and 4B.

Upon further approaching, the guide pins 77A and 77B are guided into guide holes 51 at further backsides of the holes 50A and 50B. At the same time, the split portions 74A and 74B of the relay tubes 67A and 67B are pressed into the entrance holes 50A and 50B of the second female terminals 42A and 42B to elastically deform. Accordingly, it is possible to elastically connect the first parts 4A and 4B to the second part 6. With the elastic connection, it is possible to eliminate stress generated between the attenuator 1 (male terminal) and the mating coaxial connector (female terminal) when they are fitted. Further, it is possible to allow a gap therebetween. Further, little stress is applied to the solder portions between the resistor board 62 and the relay portions 83A and 83B (the slit member 72A and 72B) and the solder portions between the resistor board 62 and the second connecting tube 82 (85).

### INDUSTRIAL APPLICABILITY

The present invention is applicable to many fields in which it is necessary to form a desirable pattern on a resistor board.

The disclosure of Japanese Patent Application No. 2005-379105, filed on Dec. 28, 2005, is incorporated in the application.

While the invention has been explained with reference to the specific embodiments of the invention, the explanation is illustrative and the invention is limited only by the appended claims.

What is claimed is:

1. A resistor board for attenuating a signal, comprising:
a first signal section for receiving the signal;
a second signal section for outputting the signal;
at least two signal lines disposed between the first signal section and the second signal section for electrically connecting the first signal section and the second signal section, each of said signal lines including a first resistor section, a first signal transmission section, and a second resistor section respectively arranged in series, said first resistor section and said second resistor section being formed of a first resistor layer, said first signal transmission section being formed of the first resistor layer and a first metal layer;
a ground section for attenuating the signal; and
a first ground line disposed between the ground section and at least one of the signal lines for electrically connecting the ground section and the at least one of the signal lines, said first ground line including a third resistor section formed of the first resistor layer.

2. The resistor board according to claim 1, wherein said first ground line is connected to the first signal transmission section of the at least one of the signal lines.

3. The resistor board according to claim 1, wherein said first ground line further includes a second signal transmission section formed of the first resistor layer and a second metal layer.

4. The resistor board according to claim 1, wherein said first ground line is connected to the at least one of the signal lines to form a first resistor block pattern having a T character shape.

5. The resistor board according to claim 1, further comprising a second ground line disposed between the ground section and the at least one of the signal lines for electrically connecting the ground section and the at least one of the signal lines, said second ground line including a fourth resistor section formed of the first resistor layer.

6. The resistor board according to claim 5, wherein said at least one of the signal lines further includes a third signal transmission section and a fourth resistor section arranged in series, said third signal transmission section being formed of the first resistor layer and a third metal layer, said fourth resistor section being formed of the first resistor layer.

7. The resistor board according to claim 6, wherein said second ground line is connected to the third signal transmission section to form a second resistor block pattern having a π character shape.

8. The resistor board according to claim 1, wherein said first signal section is formed of the first resistor layer and a fourth metal layer, and said second signal section is formed of the first resistor layer and a fifth metal layer.

9. The resistor board according to claim 1, wherein said ground section is formed of the first resistor layer and a sixth metal layer.

10. The resistor board according to claim 1, further comprising a hollow portion in an area surrounded by the first signal section, the second signal section, and the signal lines, said hollow portion not including the first resistor layer and the first metal layer.

12. The resistor board according to claim 4, wherein said first resistor block pattern is connected to a third resistor block having the T character shape in parallel.

13. The resistor board according to claim 7, wherein said second resistor block pattern is connected to a fourth resistor block having the π character shape in parallel.

14. An attenuator comprising the resistor board according to claim 1.
